(19) United States
(12) Patent Application Publication
(10) Pub. No.: US 2025/0382695 A1
(43) Pub. Date: Dec. 18, 2025

(54) DEPOSITION MASK AND METHOD OF MANUFACTURING THE DEPOSITION MASK

(71) Applicant: Samsung Display Co., LTD., Yongin-si (KR)

(72) Inventors: Young Jin SONG, Yongin-si (KR); Byeong Hoon CHO, Yongin-si (KR)

(21) Appl. No.: 19/068,144

(22) Filed: Mar. 3, 2025

(30) Foreign Application Priority Data
Jun. 14, 2024 (KR) 10-2024-0077513

(51) Int. Cl. C23C 14/04; H10K 59/12; H10K 71/16

(52) U.S. Cl. CPC C23C 14/042; H10K 59/1201; H10K 71/166

(57) ABSTRACT

Provided are a deposition mask and a method of manufacturing the deposition mask. The deposition mask includes a mask frame having a plurality of cell openings and including a rib region defining the cell openings, and a membrane including a plurality of cell regions respectively disposed above the cell openings and each having a plurality of pixel openings and a grid region disposed on the rib region. The cell regions have a residual tensile stress, and the grid region has a residual compressive stress.

This application claims priority to Korean Patent Application No. 10-2024-0077513, filed on Jun. 14, 2024, and all the benefits accruing therefrom under 35 U.S.C. § 119, the content of which in its entirety is herein incorporated by reference.

### BACKGROUND

### 1. Technical Field

The present disclosure relates to a deposition mask, a method of manufacturing the deposition mask, and an electronic device manufactured by using the deposition mask.

### 2. Description of the Related Art

Some wearable devices in which a focus is formed at a distance close to a user's eyes have been developed in the form of glasses or a helmet. For example, the wearable devices may be a head mounted display (HMD) device or AR glasses. The wearable devices may provide an augmented reality (hereinafter, referred to as “AR”) screen or a virtual reality (hereinafter, referred to as “VR”) screen to a user.

In the case of wearable devices such as an HMD device or AR glasses, a display specification of approximately 3000 PPI (pixels per inch) or higher may be implemented which allows users to use the wearable devices for a long time without symptoms of dizziness. To this end, organic light-emitting diode on silicon (OLEDoS) technology used in high-resolution small-sized organic light-emitting display devices is emerging. OLEDOS is a technology in which organic light-emitting diodes (OLEDs) are disposed on a semiconductor wafer substrate on which complementary metal oxide semiconductor (CMOS) elements are disposed.

In order to manufacture a display panel with a high resolution of about 3000 PPI or higher, a high-resolution deposition mask may be used. For example, the deposition mask may be manufactured by forming a membrane having a plurality of pixel openings on a substrate such as, for example, a silicon wafer, and partially etching the substrate to form cell openings that expose the pixel openings. However, after manufacturing the deposition mask, warpage may occur due to residual stress in the membrane, differences in thermal expansion rate between the substrate and the membrane, and the like.

### SUMMARY

Aspects and features of embodiments of the present disclosure provide an improved deposition mask capable of reducing warpage, a method of manufacturing the deposition mask, and an electronic device manufactured by using the deposition mask.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a deposition mask includes a mask frame including a plurality of cell openings and a rib region defining the cell openings, and a membrane including a plurality of cell regions respectively disposed above the cell openings and each having a plurality of pixel openings and a grid region disposed on the rib region. The cell regions have a residual tensile stress, and the grid region has a residual compressive stress.

The residual tensile stress may range from about 300 MPa to about 500 MPa, and the cell regions may be formed of an inorganic material.

The residual compressive stress may range from about-500 MPa to about-300 MPa, and the grid region may be formed of an inorganic material.

The membrane may further include intermediate regions disposed between the cell regions and the grid region and respectively surrounding the cell regions.

The intermediate regions may have a residual stress ranging from about-500 MPa to about 500 MPa and may be formed of an inorganic material.

Each of the intermediate regions may be partially exposed by a cell opening of the cell openings.

The deposition mask may further include an inorganic film pattern disposed on a rear surface of the mask frame.

The inorganic film pattern may have a residual stress equal to the residual stress of the cell regions.

The deposition mask may further include a protective film disposed on the cell regions.

The protective film may include a metal oxide or a metal nitride.

According to one or more embodiments of the present disclosure, a method of manufacturing a deposition mask includes forming a membrane including cell regions and a grid region disposed between the cell regions on a substrate, and forming cell openings which respectively expose the cell regions by partially removing the substrate. The cell regions have a residual tensile stress, and the grid region has a residual compressive stress.

The forming of the membrane may include forming, on the substrate, a first inorganic film having the residual tensile stress, forming the cell regions by patterning the first inorganic film, and forming the grid region between the cell regions.

The forming of the grid region may include forming, on the substrate and the cell regions, a second inorganic film having the residual compressive stress, and forming the grid region between the cell regions by performing a planarization process, wherein the grid region exposes the cell regions.

The forming of the membrane may further include forming intermediate regions respectively surrounding the cell regions between the cell regions and the grid region.

The residual tensile stress may range from about 300 MPa to about 500 MPa, the residual compressive stress may range from about-500 MPa to about-300 MPa, and the intermediate regions may have a residual stress ranging from about-500 MPa to about 500 MPa.

The method may further include forming a rear inorganic film on a rear surface of the substrate. The forming of the cell openings may include forming, by patterning the rear inorganic film, an inorganic film pattern exposing portions where the cell openings are to be formed, and performing an etching process using the inorganic film pattern as an etch mask in association with forming the cell openings.

The first inorganic film and the rear inorganic film may be formed simultaneously through a thermal chemical vapor deposition process.

The forming of the membrane may include forming, on the substrate, a first inorganic film having the residual tensile stress, forming the cell regions by patterning the first inorganic film, forming, on the substrate and the cell regions, a second inorganic film having the residual compressive stress, performing an etching process which forms trenches respectively surrounding the cell regions, forming a third inorganic film which fills the trenches, and performing a planarization process which exposes the cell regions. In such case, the grid region may be formed between the cell regions by the planarization process, and intermediate regions respectively surrounding the cell regions may be formed between the cell regions and the grid region by the planarization process.

The forming of the membrane may further include, after forming the second inorganic film, performing a planarization process which planarizes the second inorganic film.

The second inorganic film and the third inorganic film may be formed through a plasma-enhanced chemical vapor deposition process.

The method may further include forming, at each cell region of the cell regions, a plurality of pixel openings penetrating the cell region, and forming a protective film on the cell regions after forming the cell openings.

According to one or more embodiments of the present disclosure, an electronic device may include a display panel. The display panel may include a backplane substrate and light-emitting layers formed on the backplane substrate by using a deposition mask. The deposition mask may include a mask frame and a membrane. The mask frame may include a plurality of cell openings and a rib region defining the cell openings. The membrane may include a plurality of cell regions respectively disposed above the cell openings and each having a plurality of pixel openings, and a grid region disposed on the rib region. The cell regions may have a residual tensile stress, and the grid region may have a residual compressive stress.

According to the embodiments of the present disclosure, warpage of cell regions (hereinafter, referred to as ‘cell warpage’) may be reduced by residual tensile stress of the cell regions, and the overall warpage of the deposition mask (hereinafter, referred to as ‘global warpage’) may be reduced by residual compressive stress of a grid region.

However, effects according to the embodiments of the disclosure are not limited to those described herein and various other effects are incorporated herein.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view illustrating a display device;

FIG. 2 is a block diagram for explaining the display device illustrated in FIG. 1;

FIG. 3 is an equivalent circuit diagram for explaining an example of a first sub-pixel illustrated in FIG. 2;

FIG. 4 is a schematic plan view illustrating an example of the display panel illustrated in FIG. 1;

FIG. 5 is a schematic plan view illustrating an example of the display area illustrated in FIG. 4;

FIG. 6 is a schematic plan view illustrating another example of the display area illustrated in FIG. 4;

FIG. 7 is a cross-sectional view illustrating an example of the display panel taken along line I-I′ of FIG. 5;

FIG. 8 is a schematic perspective view illustrating an example of a head mounted display;

FIG. 9 is a schematic exploded perspective view illustrating the head mounted display illustrated in FIG. 8;

FIG. 10 is a schematic perspective view illustrating another example of a head mounted display;

FIG. 11 is a schematic plan view illustrating a deposition mask according to an embodiment of the present disclosure;

FIG. 12 is a schematic plan view illustrating cell regions and a grid region illustrated in FIG. 11;

FIG. 13 is a schematic cross-sectional view taken along line II-II′ illustrated in FIG. 12;

FIG. 14 is a cross-sectional view illustrating a deposition mask according to another embodiment of the present disclosure;

FIG. 15 is a schematic plan view illustrating a deposition mask according to still another embodiment of the present disclosure;

FIG. 16 is a schematic cross-sectional view taken along line III-III′ illustrated in FIG. 15;

FIG. 17 is a schematic cross-sectional view illustrating a deposition mask according to still another embodiment of the present disclosure;

FIGS. 18 to 24 are schematic cross-sectional views illustrating a method of manufacturing a deposition mask according to still another embodiment of the present disclosure; and

FIGS. 25 to 31 are schematic cross-sectional views illustrating a method of manufacturing a deposition mask according to still another embodiment of the present disclosure.

### DETAILED DESCRIPTION

Embodiments of the present disclosure will now be described more fully hereinafter with reference to the accompanying drawings, in which various embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will filly convey the scope of example aspects of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings supported by aspects of the present disclosure. Similarly, the second element could also be termed the first element.

The terminology used herein is for the purpose of describing particular embodiments and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

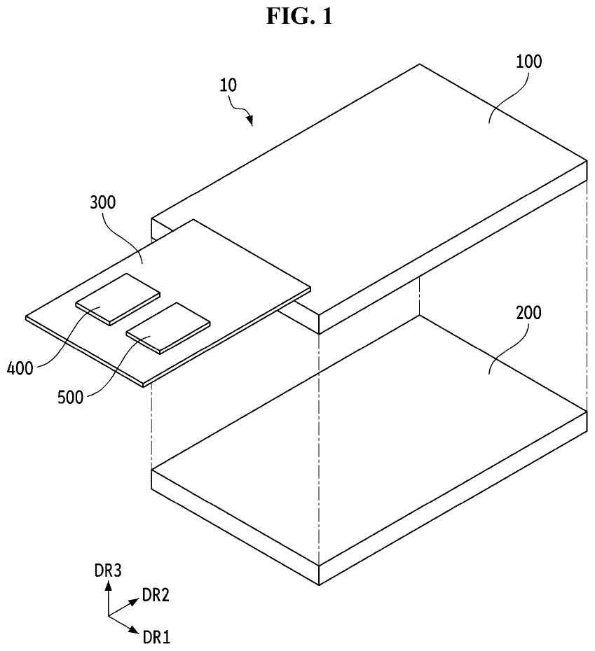

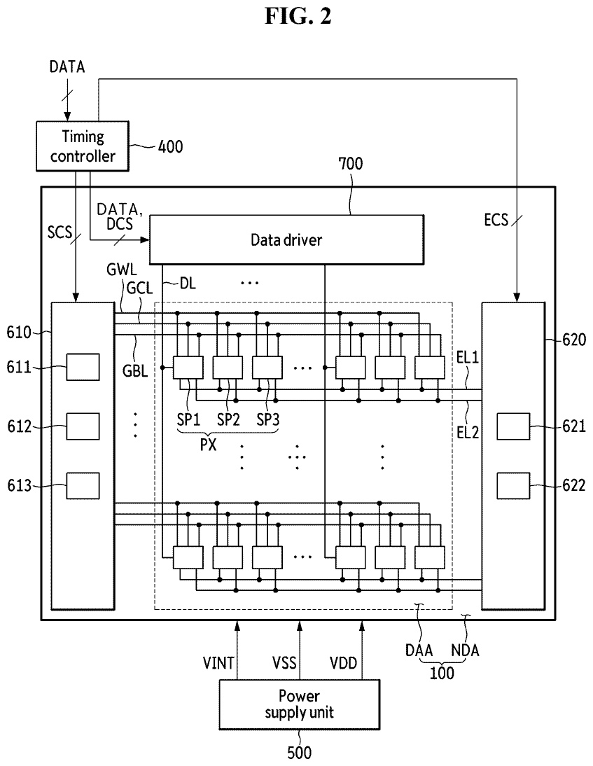

FIG. 1 is an exploded perspective view illustrating a display device. FIG. 2 is a block diagram for explaining the display device illustrated in FIG. 1.

Referring to FIGS. 1 and 2, a display device 10 may be a device displaying a moving image or a still image. The display device 10 may be applied to portable electronic devices such as, for example, a mobile phone, a smartphone, a tablet personal computer (PC), a mobile communication terminal, an electronic organizer, an electronic book, a portable multimedia player (PMP), a navigation system, an ultra-mobile PC (UMPC) or the like. For example, the display device 10 may be applied as a display unit of electronic devices such as, for example, a television, a laptop, a monitor, a billboard, an Internet-of-Things (IoT) device, and the like. Alternatively, the display device 10 may be applied to electronic devices such as, for example, a smart watch, a watch phone, a head mounted display (HMD) for implementing virtual reality and augmented reality, and the like.

The display device 10 may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. As illustrated in FIG. 2, the display panel 100 may be divided into a display area DAA displaying an image and a non-display area NDA not displaying an image.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

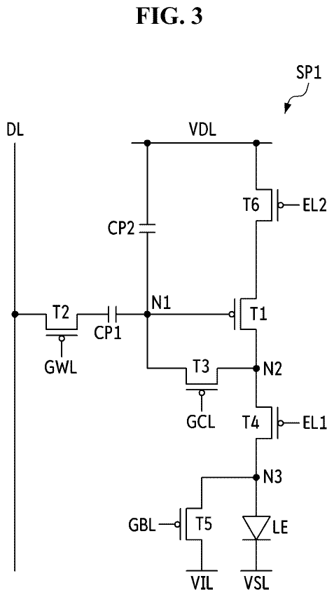

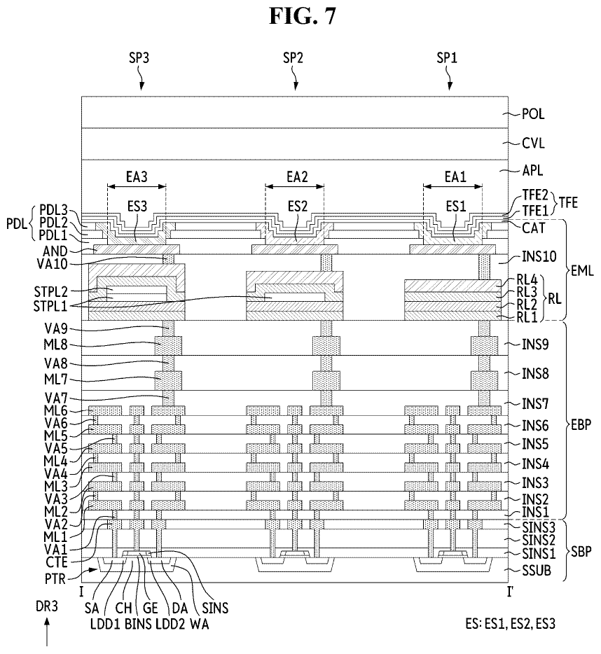

The plurality of pixels PX may include a plurality of sub-pixels SP1, SP2, and SP3. The plurality of sub-pixels SP1, SP2, and SP3 may include a plurality of pixel transistors (see FIG. 3). The plurality of pixel transistors may be formed by a semiconductor process, and may be disposed on a semiconductor substrate SSUB (see FIG. 7). For example, the plurality of pixel transistors of the data driver 700 may be formed through a complementary metal oxide semiconductor (CMOS) process, but embodiments of the present disclosure are not limited thereto.

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include a plurality of scan transistors, and the emission driver 620 may include a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed through a CMOS process, but the embodiment of the present specification is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed through a semiconductor process, and formed on the semiconductor substrate SSUB (see FIG. 7). For example, the plurality of data transistors may be formed through a CMOS process, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface of the display panel 100. The heat dissipation layer 200 serves to dissipate heat generated from the display panel 100. The heat dissipation layer 200 may include a metal layer having high thermal conductivity, such as, for example, graphite, silver (Ag), copper (Cu), or aluminum (Al).

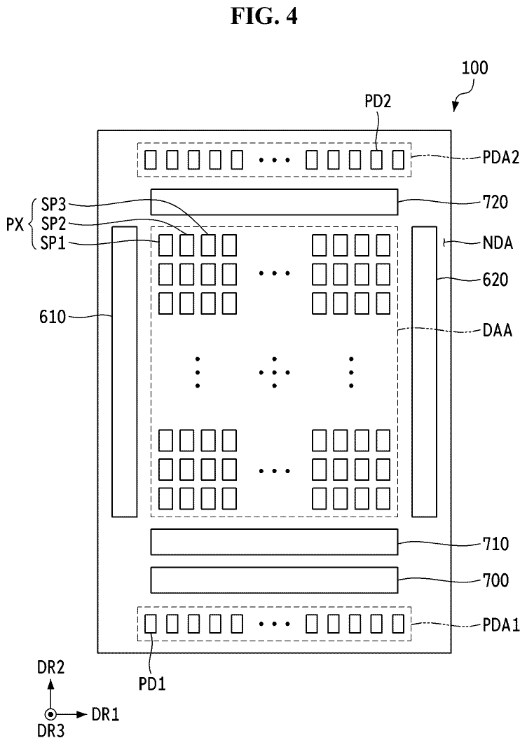

The circuit board 300 may be electrically connected to a plurality of first pads PD1 (see FIG. 4) of a first pad portion PDA1 (see FIG. 4) of the display panel 100 by using a conductive adhesive member such as, for example, an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

As another example, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process, and formed on the semiconductor substrate SSUB (see FIG. 7). For example, the plurality of timing transistors and the plurality of power transistors may be formed through a CMOS process, but embodiments of the present disclosure are not limited thereto. Each of the timing control circuit 400 and the power supply circuit 500 may be disposed between the data driver 700 and the first pad portion PDA1 (see FIG. 4).

FIG. 3 is an equivalent circuit diagram for explaining an example of a first sub-pixel illustrated in FIG. 2.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but embodiments of the present disclosure are not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode of the first transistor T1 according to a voltage applied to the gate electrode of the first transistor T1. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that illustrated in FIG. 3. For example, the number of transistors and the number of capacitors of the first sub-pixel SP1 are not limited to those illustrated in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 will be omitted in the present disclosure.

FIG. 4 is a schematic plan view illustrating an example of the display panel illustrated in FIG. 1.

Referring to FIG. 4, the display area DAA of the display panel 100 may include the plurality of pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, as illustrated in FIG. 4, the scan driver 610 may be disposed on the left side of the display area DAA, and the emission driver 620 may be disposed on the right side of the display area DAA. However, embodiments of the present disclosure are not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2. That is, as illustrated in FIG. 4, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or probe pins during an inspection process, or may be connected to a circuit board for inspection. The circuit board for inspection may be a printed circuit board formed of a rigid material or a flexible printed circuit board formed of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2. That is, as illustrated in FIG. 4, the second pad portion PDA2 may be disposed closer to the edge of the display panel 100 than the second distribution circuit 720.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, as illustrated in FIG. 4, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, as illustrated in FIG. 4, the second distribution circuit 720 may be disposed on the upper side of the display area DAA.

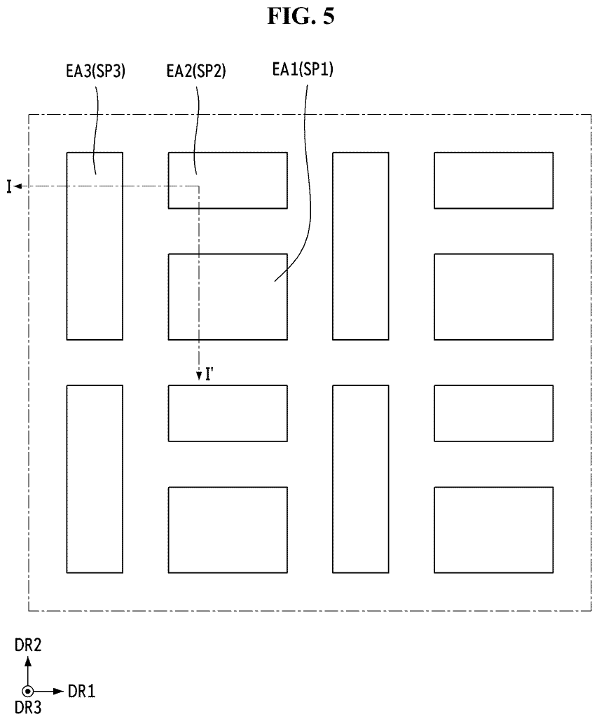

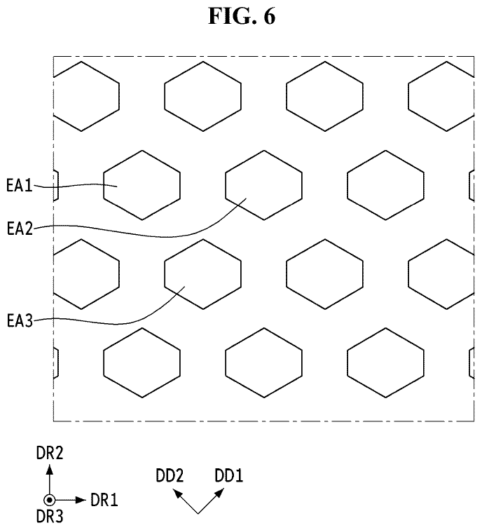

FIG. 5 is a schematic plan view illustrating an example of the display area illustrated in FIG. 4. FIG. 6 is a schematic plan view illustrating another example of the display area illustrated in FIG. 4.

Referring to FIG. 5, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel defining film PDL (see FIG. 7). For example, each of the first emission area EA1, the second emission area EA2, and the third emission area EA3 may be an area defined by a first pixel defining film PDL1 (see FIG. 7).

The length of the third emission area EA3 in the first direction DR1 may be less than the length of the first emission area EA1 in the first direction DR1, and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2, and the length of the second emission area EA2 in the second direction DR2. The length of the first emission area EA1 in the second direction DR2 may be greater than the length of the second emission area EA2 in the second direction DR2.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different from each other.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

As another example, as illustrated in FIG. 6, the first emission area EA1, the second emission area EA2, and the third emission area EA3 may be disposed in a hexagonal structure having a hexagonal shape in plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

Although it is illustrated in FIGS. 5 and 6 that each of the plurality of pixels PX includes the three emission areas EA1, EA2, and EA3, embodiments of the present disclosure are not limited thereto. That is, each of the plurality of pixels PX may include four emission areas. Further, each of the emission areas EA1, EA2, and EA3 may have a polygonal, circular, elliptical, or atypical shape in plan view, unlike those illustrated in FIGS. 5 and 6.

The arrangement of the emission areas EA1, EA2, and EA3 of the plurality of pixels PX is not limited to that illustrated in FIGS. 5 and 6. For example, the emission areas of the plurality of pixels PX may be disposed in a stripe structure in which the emission areas are arranged in the first direction DR1, a PenTile® structure in which the emission areas are arranged in a diamond shape, or the like.

FIG. 7 is a cross-sectional view illustrating an example of the display panel taken along line I-I′ of FIG. 5.

Referring to FIG. 7, the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed at top surface portions of the semiconductor substrate SSUB. The plurality of well regions WA may be regions doped with a second type impurity. The second type impurity may be different from the aforementioned first type impurity. In an example in which the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode of the pixel transistor PTR, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than an impurity concentration of the source region SA. The second low-concentration impurity region LDD2 may be a region having an impurity concentration lower than an impurity concentration of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, such that punch-through and hot carrier phenomena that might be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) or a silicon oxide (SiOx)-based inorganic film, but embodiments of the present disclosure are not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the embodiment of the present specification is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through contact plugs penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on side surfaces of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the embodiment of the present specification is not limited thereto.

The semiconductor substrate SSUB may be replaced with a glass substrate or a polymer resin substrate such as, for example, polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include a plurality of conductive layers ML1 to ML8, a plurality of vias VA1 to VA9, and a plurality of insulating films INS1 to INS9. The plurality of insulating films INS1 to INS9 may be used for electrical insulation between the plurality of conductive layers ML1 to ML8.

The first to eighth conductive layers ML1 to ML8 are connected to the plurality of contact terminals CTE exposed from the semiconductor backplane SBP, and serve to implement the circuit of the first sub-pixel SP1 illustrated in FIG. 3. For example, the first to sixth transistors T1 to T6 are merely formed in the semiconductor backplane SBP, and the connection of the first to sixth transistors T1 to T6 and the first and second capacitors C1 and C2 may be implemented by the first to eighth conductive layers ML1 to ML8. In some aspects, the connection between the drain region corresponding to the drain electrode of the fourth transistor T4, the source region corresponding to the source electrode of the fifth transistor T5, and a first electrode AND of the light-emitting element LE (see FIG. 3) may also be implemented by the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the seventh conductive layer ML7. Each of the eighth conductive layers ML8 may be disposed on the eighth insulating film INS8 and may be connected to the eighth via VA8.

The first to eighth conductive layers ML1 to ML8 may be formed of substantially the same material. The first to eighth conductive layers ML1 to ML8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be formed of substantially the same material. The first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. First to eighth insulating films INS1 to INS8 may be formed of a silicon oxide (SiOx)-based inorganic film, but the embodiment of the present specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9,000 Å. The thickness of each of the seventh via VA7 and the eighth via VA8 may be approximately 6,000 Å.

A ninth insulating film INS9 may be disposed on the eighth insulating film INS8 and the eighth conductive layer ML8. The ninth insulating film INS9 may be formed of a silicon oxide (SiOx)-based inorganic film, but the embodiment of the present specification is not limited thereto.

Each of the ninth vias VA9 may penetrate the ninth insulating film INS9 and be connected to the eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode RL1, RL2, RL3, and RL4, a first step layer STPL1, and a second step layer STPL2. For example, the reflective electrode layer RL may include first to fourth reflective electrodes RL1, RL2, RL3, and RL4 as illustrated in FIG. 7.

Each of the first reflective electrodes RL1 may be disposed on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

The first step layer STPL1 may be disposed on the second reflective electrode RL2 in the second sub-pixel SP2 and the third sub-pixel SP3. The first step layer STPL1 may be disposed such that the first step layer STPL1 is not on the second reflective electrode RL2 in the first sub-pixel SP1.

The second step layer STPL2 may be disposed on the first step layer STPL1 in the third sub-pixel SP3. The second step layer STPL2 may be disposed such that the second step layer STPL2 is not on the second reflective electrode RL2 in the first sub-pixel SP1. In some aspects, the second step layer STPL2 may be disposed such that the second step layer STPL2 is not on the first step layer STPL1 in the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 to advantageously reflect the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RL4 to advantageously reflect the light of the third color emitted from the light-emitting stack ES.

The first step layer STPL1 and the second step layer STPL2 may be formed of silicon carbonitride (SiCN) or a silicon oxide (SiOx)-based inorganic film, but the embodiment of the present specification is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

At least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include metal having high reflectivity to advantageously reflect the light. In some aspects, since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include aluminum (Al) or titanium (Ti).

The tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, among light emitted from the light-emitting elements LE. The tenth insulating film INS10 may be formed of a silicon oxide (SiOx)-based inorganic film, but embodiments of the present disclosure are not limited thereto.

Each of the tenth vias VA10 may penetrate the tenth insulating film VA10 and be connected to the reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The thicknesses of the tenth vias VA10 may be different in the first sub-pixel SP1, the second sub-pixel SP2, and the third sub-pixel SP3 in order to adjust a resonance distance of light emitted from the light-emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. That is, the distance between the light-emitting stack ES and the reflective electrode layer RL may be different in the first sub-pixel SP1, the second sub-pixel SP2, and the third sub-pixel SP3.

In summary, in order to adjust the distance between the light-emitting stack ES and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TiN).

The pixel defining film PDL may be disposed on the tenth insulating film INS10 and a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3. That is, the pixel defining film PDL may have openings that partially expose the first electrode AND of each of the light-emitting elements LE.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film, but the embodiment of the present specification is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, such that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

The light-emitting stack ES may include a first light-emitting stack ES1 disposed in the first emission area EA1, a second light-emitting stack ES2 disposed in the second emission area EA2, and a third light-emitting stack ES3 disposed in the third emission area EA3. Although not illustrated in detail, the first light-emitting stack ES1 may include a hole injecting layer HIL, a hole transporting layer HTL, a first light-emitting layer EML1, an electron transporting layer ETL, and an electron injecting layer EIL, the second light-emitting stack ES2 may include the hole injecting layer HIL, the hole transporting layer HTL, a second light-emitting layer EML2, the electron transporting layer ETL, and the electron injecting layer EIL, and the third light-emitting stack ES3 may include the hole injecting layer HIL, the hole transporting layer HTL, a third light-emitting layer EML3, the electron transporting layer ETL, and the electron injecting layer EIL.

For example, the hole injecting layer HIL may be disposed on the first electrodes AND exposed by the openings of the pixel defining film PDL, the inner surfaces of the openings of the pixel defining film PDL, and the top surface of the pixel defining film PDL. The hole transporting layer HTL may be disposed on the hole injecting layer HIL.

The first to third light-emitting layers EML1, EML2, and EML3 may be respectively disposed in the openings of the pixel defining film PDL on the hole transporting layer HTL. The first light-emitting layer EML1 may be disposed in the opening of the pixel defining film PDL in the first emission area EA1, and may emit light of a first color, for example, red light. The second light-emitting layer EML2 may be disposed in the opening of the pixel defining film PDL in the second emission area EA2, and may emit light of a second color, for example, green light. The third light-emitting layer EML3 may be disposed in the opening of the pixel defining film PDL in the third emission area EA3, and may emit light of a third color, for example, blue light.

The electron transporting layer ETL may be disposed on the first to third light-emitting layers EML1, EML2, and EML3 and the hole transporting layer HTL, and the electron injecting layer EIL may be disposed on the electron transporting layer ETL.

In another example, although not illustrated, a plurality of trenches (not illustrated) may be disposed between the first to third emission areas EA1, EA2, and EA3. The trenches may have a ring shape respectively surrounding the first to third emission areas EA1, EA2, and EA3, and may be formed to penetrate the pixel defining film PDL. The hole injecting layer HIL and the hole transporting layer HTL formed on the first electrodes AND of the first to third emission areas EA1, EA2, and EA3 may be disconnected from each other by the trenches.

In another example, the first to third light-emitting stacks ES1, ES2, and ES3 may be respectively disposed in the openings of the pixel defining film PDL, and may not be disposed on the pixel defining film PDL. In this case, the first to third light-emitting stacks ES1, ES2, and ES3 may be disconnected from each other by the pixel defining film PDL.

The second electrode CAT may be disposed on the first to third light-emitting stacks ES1, ES2, and ES3. The second electrode CAT may be formed of a transparent conductive material (TCO) such as, for example, ITO or IZO that can transmit light or a semi-transmissive conductive material such as, for example, magnesium (Mg), silver (Ag), or an alloy of Mg and Ag. In an example in which the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxynitride (SiON), and silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) or aluminum oxide (AlOx), but the embodiment of the present specification is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The adhesive layer APL may be a layer for increasing the interfacial adhesion between the encapsulation layer TFE and the cover layer CVL. The adhesive layer APL may be an organic film such as, for example, acrylic resin, epoxy resin, phenolic resin, polyamide resin, or polyimide resin.

The cover layer CVL may be disposed on the adhesive layer APL. The cover layer CVL may be a glass substrate or a polymer resin. In an example in which the cover layer CVL is a glass substrate, the cover layer CVL may be attached onto the adhesive layer APL, and may serve as an encapsulation substrate. In an example in which the cover layer CVL is a polymer resin, the cover layer CVL may be directly applied onto the adhesive layer APL.

The polarizing plate POL may be disposed on the cover layer CVL. The polarizing plate POL may be a structure for reducing or preventing visibility degradation caused by reflection of external light. The polarizing plate POL may include a linear polarizing plate and a phase retardation film. For example, the phase retardation film may be a 24 plate (quarter-wave plate), but embodiments of the present disclosure are not limited thereto.

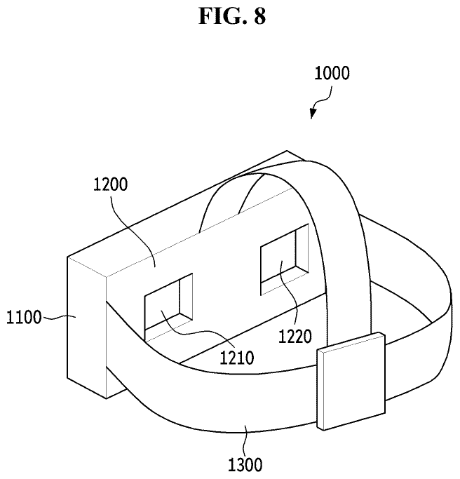

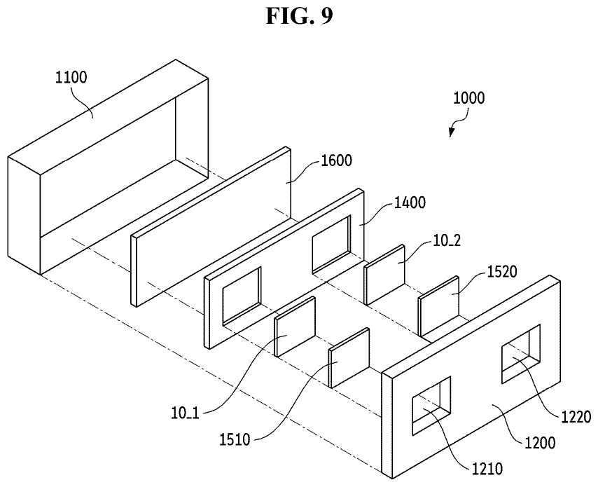

FIG. 8 is a schematic perspective view illustrating a head mounted display. FIG. 9 is a schematic exploded perspective view illustrating an example of the head mounted display illustrated in FIG. 8.

Referring to FIGS. 8 and 9, a head mounted display 1000 according to an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 provides an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first and second display devices 10_1 and 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed such that the housing cover 1200 covers an open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

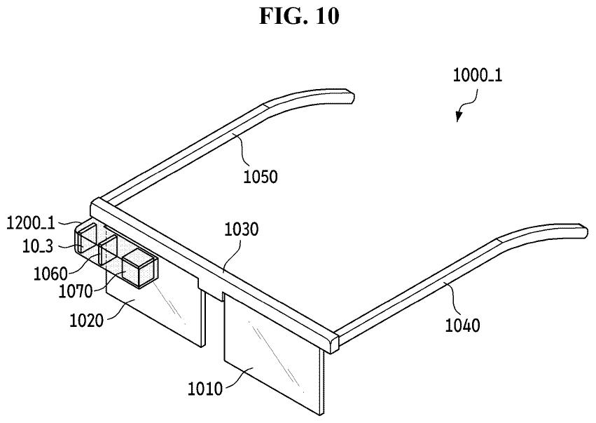

The head mounted band 1300 serves to secure the display device housing 1100 to the user's head such that the first eyepiece 1210 and the second eyepiece 1220 of the housing cover 1200 remain located on the user's left and right eyes, respectively. In an example in which the display device housing 1100 is implemented to be lightweight and compact, the head mounted display 1000 may be provided in the form of glasses as illustrated in FIG. 10.

In some aspects, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating another example of a head mounted display.

Referring to FIG. 10, a head mounted display 1000_1 may be an eyeglasses-type display device in which a display device housing 1200_1 is implemented in a lightweight and compact manner. The head mounted display 1000_1 may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. The image displayed on the display device 10_3 may be magnified by the optical member 1060, and may be provided to the user's right eye through the right eye lens 1020 after the optical path of the image is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but embodiments of the present disclosure are not limited thereto. For example, the display device housing 1200_1 may be disposed at the left end of the support frame 1030, and in this case, the image of the display device 10_3 may be provided to the user's left eye. As another example, the display device housing 1200_1 may be disposed at both the left and right ends of the support frame 1030, and in this case, the user may view the image displayed on the display device 10_3 through both the left and right eyes.

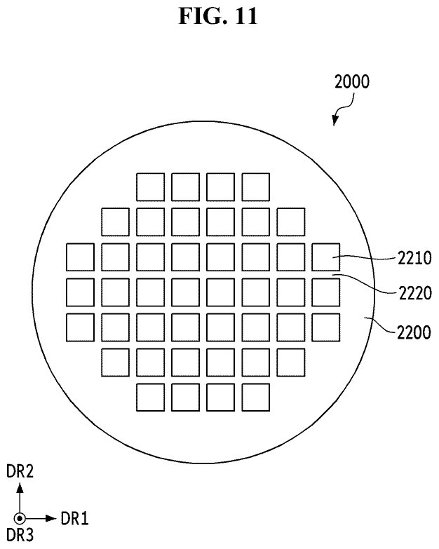

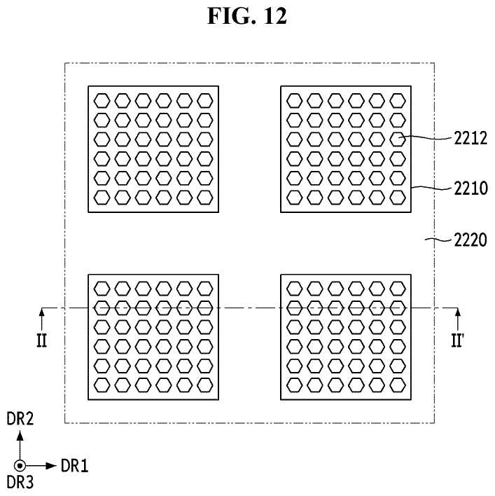

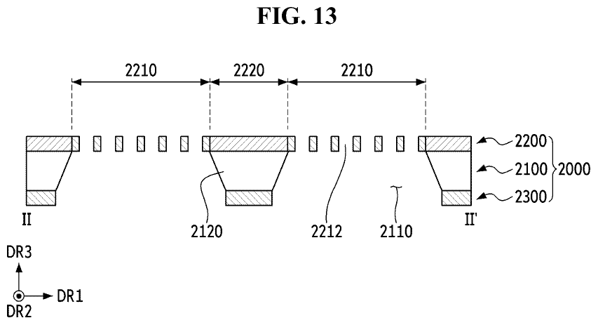

FIG. 11 is a schematic plan view illustrating a deposition mask according to an embodiment of the present disclosure. FIG. 12 is a schematic plan view illustrating cell regions and a grid region illustrated in FIG. 11. FIG. 13 is a schematic cross-sectional view taken along line II-II′ illustrated in FIG. 12.

Referring to FIGS. 11 to 13, a deposition mask 2000 according to an embodiment of the present disclosure may be used as a shadow mask in a deposition process for forming light-emitting layers of a light-emitting stack ES on a backplane substrate. According to an embodiment of the present disclosure, a deposition mask 2000 may be used to form light-emitting layers of the light-emitting stack ES on the backplane substrate in a manufacturing process of the display panel 100 (see FIG. 1). For example, as illustrated in FIG. 7, the semiconductor backplane SBP and the light emitting element backplane EBP may be disposed on the backplane substrate, and the reflective electrodes RL and the insulating film INS10 may be disposed on the light emitting element backplane EBP. Electrode patterns, for example, the first electrodes AND may be disposed on the insulating film INS10, and the first electrodes AND may be electrically connected to the reflective electrodes RL through the vias VA10. For example, the deposition mask 2000 may be used to form light-emitting layers on the electrode patterns. As an example, the deposition mask 2000 may be used to form first light-emitting layers for emitting first light having a red wavelength band on the first electrodes AND of the first emission areas EA1. As another example, the deposition mask 2000 may be used to form second light-emitting layers for emitting second light having a green wavelength band on the first electrodes AND of the second emission areas EA2. As still another example, the deposition mask 2000 may be used to form third light-emitting layers for emitting third light having a blue wavelength band on the first electrodes AND of the third emission areas EA3.

According to an embodiment of the present disclosure, the deposition mask 2000 may include a mask frame 2100 and a membrane 2200 disposed on the mask frame 2100. For example, a substrate such as, for example, a silicon wafer may be used as the mask frame 2100, and the membrane 2200 may include inorganic films formed on the substrate.

The membrane 2200 may include one or more cell regions 2210. For example, as illustrated in FIG. 11, the membrane 2200 may include a plurality of cell regions 2210 arranged in a matrix form along a first direction DR1 and a second direction DR2 that intersects the first direction DR1, and a grid region 2220 disposed between the cell regions 2210. For example, the second direction DR2 may be a direction perpendicular to the first direction DR1. However, since the number and arrangement direction of the cell regions 2210 may be varied, the scope of the present disclosure will not be limited thereby.

The mask frame 2100 may have a plurality of cell openings 2110 that expose the cell regions 2210 of the membrane 2200, and may include a rib region 2120 that defines the cell openings 2110. In this case, the cell regions 2210 of the membrane 2200 may be respectively disposed above the cell openings 2110 of the mask frame 2100, and the grid region 2220 of the membrane 2200 may be disposed on the rib region 2120 of the mask frame 2100.

Each of the cell regions 2210 of the membrane 2200 may have a plurality of pixel openings 2212. The plurality of pixel openings 2212 may be formed to penetrate each of the cell regions 2210. That is, the pixel openings 2212 of the membrane 2200 may communicate with the cell openings 2110 of the mask frame 2100. The cell openings 2110 of the mask frame 2100 and the pixel openings 2212 of the membrane 2200 may function as paths for providing light-emitting materials onto the anode electrodes of the backplane substrate in the deposition process for forming light-emitting layers. For example, as illustrated in FIG. 12, the pixel openings 2212 may be arranged in a matrix form along the first direction DR1 and the second direction DR2.

According to an embodiment of the present disclosure, the cell regions 2210 of the membrane 2200 may be formed of an inorganic material such as, for example, silicon nitride, and may be formed such that the cell regions 2210 have a residual tensile stress supportive of reducing the cell warpage. For example, the cell regions 2210 may be formed through a thermal chemical vapor deposition (TCVD) process, and the residual tensile stress of the cell regions 2210 may be appropriately adjusted in a range of about 300 MPa to about 500 MPa according to the size of the cell regions 2210.

An inorganic film pattern 2300 may be disposed on a rear surface of the mask frame 2100 that is opposite to a front surface of the mask frame 2100 on which the membrane 2200 is disposed. The inorganic film pattern 2300 may be used as an etch mask in an etching process for forming the cell openings 2110, and may be formed of the same material as the cell regions 2210 of the membrane 2200. For example, the cell regions 2210 and the inorganic film pattern 2300 may be formed simultaneously by a batch type deposition apparatus for performing the TCVD process. Thus, the inorganic film pattern 2300 may have a residual stress equal to the residual stress of the cell regions 2210. That is, the inorganic film pattern 2300 may be formed of silicon nitride and may have a residual tensile stress of about 300 MPa to about 500 MPa.

When the membrane 2200 and the inorganic film pattern 2300 are respectively disposed on the front and rear surfaces of the mask frame 2100 as described herein, the area of the membrane 2200 may be different from the area of the inorganic film pattern 2300. Accordingly, the force applied from the membrane 2200 to the mask frame 2100 may be different from the force applied from the inorganic film pattern 2300 to the mask frame 2100. As a result, after manufacturing the deposition mask 2000, global warpage may occur in the deposition mask 2000 due to the force difference.

According to an embodiment of the present disclosure, the grid region 2220 of the membrane 2200 may be formed of an inorganic material such as, for example, silicon nitride, and may have a residual compressive stress to reduce the global warpage of the deposition mask 2000. Specifically, the grid region 2220 of the membrane 2200 may be disposed on the rib region 2120 of the mask frame 2100, and may have a residual compressive stress such that the force applied from the membrane 2200 to the mask frame 2100 may be balanced with the force applied from the inorganic film pattern 2300 to the mask frame 2100. For example, the grid region 2220 of the membrane 2200 may be formed through a plasma-enhanced chemical vapor deposition (PECVD) process, and may have a residual compressive stress of about-500 MPa to about-300 MPa. That is, the residual stress of the grid region 2220 may be adjusted appropriately in a range of about-500 MPa to about-300 MPa according to the size and number of the cell regions 2210 and the residual stresses of the cell regions 2210 and the inorganic film pattern 2300.

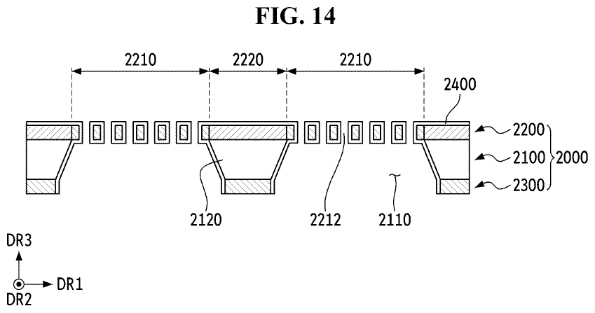

FIG. 14 is a cross-sectional view illustrating a deposition mask according to another embodiment of the present disclosure.

Referring to FIG. 14, the deposition mask 2000 according to another embodiment of the present disclosure may include the mask frame 2100 and the membrane 2200. The mask frame 2100 may have the plurality of cell openings 2110 and may include the rib region 2120 that defines the cell openings 2110. The membrane 2200 may include the cell regions 2210 each disposed above the cell opening 2110 of the mask frame 2100 and having the plurality of pixel openings 2212, and the grid region 2220 disposed on the rib region 2120 of the mask frame 2100. In particular, the cell regions 2210 of the membrane 2200 may have a residual tensile stress, and the grid region 2220 of the membrane 2200 may have a residual compressive stress.

According to this embodiment, the deposition mask 2000 may include a protective film 2400 disposed on the cell regions 2210. Specifically, while performing a deposition process for forming light-emitting layers on a backplane substrate, a light-emitting layer (not illustrated) may be formed on the surfaces of the deposition mask 2000. After the deposition process is performed, a cleaning process may be performed to remove the light-emitting layer on the deposition mask 2000. The protective film 2400 according to this embodiment may be used to protect the cell regions 2210 during the cleaning process, and may be formed of a metal oxide or a metal nitride.

For example, the protective film 2400 may be formed such that the thickness of the protective film 2400 is several to several tens of nanometers (nm) through an atomic layer deposition (ALD) process. In this case, the protective film 2400 may be formed not only on the cell regions 2210 but also on the rib region 2120 and the grid region 2220, as illustrated in FIG. 14. In some aspects, the protective film 2400 may be formed of a metal oxide such as, for example, aluminum oxide (Al₂O₃), or a metal nitride such as, for example, titanium nitride (TiN) and tungsten nitride (WN). As another example, the protective film 2400 may be formed through a chemical vapor deposition or physical vapor deposition process. In this embodiment, since the remaining components except for the protective film 2400 are substantially the same as those described herein with reference to FIGS. 11 to 13, detailed description thereof will be omitted.

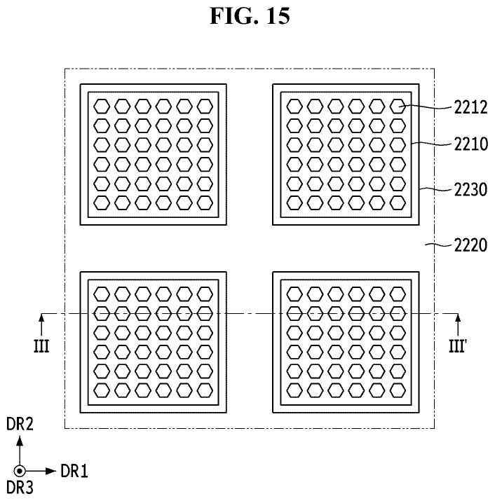

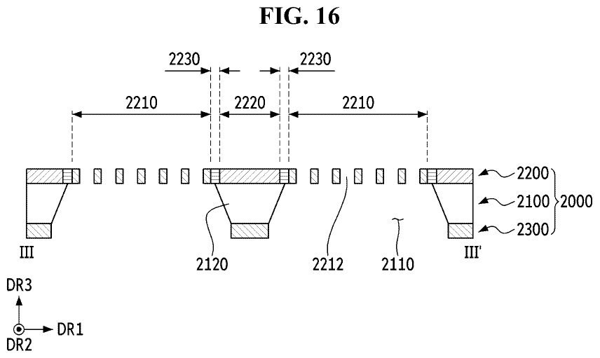

FIG. 15 is a schematic plan view illustrating a deposition mask according to still another embodiment of the present disclosure. FIG. 16 is a schematic cross-sectional view taken along line III-III′ illustrated in FIG. 15.

Referring to FIGS. 15 and 16, the deposition mask 2000 according to still another embodiment of the present disclosure may include the mask frame 2100 and the membrane 2200. The mask frame 2100 may have the plurality of cell openings 2110 and may include the rib region 2120 that defines the cell openings 2110. The membrane 2200 may include the cell regions 2210 each disposed above the cell opening 2110 of the mask frame 2100 and having the plurality of pixel openings 2212 and the grid region 2220 disposed on the rib region 2120 of the mask frame 2100. In particular, the cell regions 2210 of the membrane 2200 may have a residual tensile stress, and the grid region 2220 of the membrane 2200 may have a residual compressive stress.

According to this embodiment, the membrane 2200 may include intermediate regions 2230 disposed between the cell regions 2210 and the grid region 2220 and respectively surrounding the cell regions 2210. The intermediate regions 2230 may be used to reduce both the cell warpage and the global warpage of the deposition mask 2000. That is, the intermediate regions 2230 may function as buffer regions between the cell regions 2210 and the grid region 2220 to reduce the cell warpage, and may also assist the function of the grid region 2220 to reduce the global warpage.

For example, the intermediate regions 2230 may be formed of silicon nitride and may be formed through a PECVD process such that the intermediate regions 2230 have a residual stress ranging from about-500 MPa to about 500 MPa. Particularly, the intermediate regions 2230 may have a residual stress less than the residual stress of the cell regions 2210. In some aspects, the intermediate regions 2230 may be disposed between the cell regions 2210 and the grid region 2220 and may be partially exposed through the cell openings 2110. That is, the intermediate regions 2230 may have a ring shape surrounding each of the cell regions 2210 as illustrated in FIG. 15. The inner portion of each of the intermediate regions 2230 may be partially exposed by each of the cell openings 2110 as illustrated in FIG. 16.

In particular, in a wet etching process which may form the cell openings 2110, when an aqueous solution of tetramethylammonium hydroxide (TMAH, (CH₃)₄NOH) is used, the etch rate may be increased at edge portions of the cell openings 2110 by hydrogen (H₂) bubbles generated during the etching process, which may cause damage due to stress concentration at the edge portions of the cell regions 2210. According to this embodiment, stress concentration may be reduced in the etching process for forming the cell openings 2110 by using the intermediate regions 2230 which have a residual stress less than the residual stress of the cell regions 2210. Accordingly, damage to the cell regions 2210 may be sufficiently reduced or prevented during the etching process.

In this embodiment, since the remaining components except for the intermediate regions 2230 are substantially the same as those described herein with reference to FIGS. 11 to 13, detailed description thereof will be omitted.

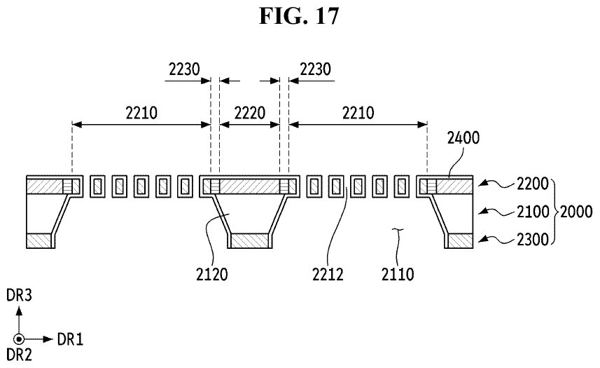

FIG. 17 is a schematic cross-sectional view illustrating a deposition mask according to still another embodiment of the present disclosure.

Referring to FIG. 17, the deposition mask 2000 according to still another embodiment of the present disclosure may include the mask frame 2100 and the membrane 2200. The mask frame 2100 may have the plurality of cell openings 2110 and may include the rib region 2120 that defines the cell openings 2110. The membrane 2200 may include the cell regions 2210 each disposed above the cell opening 2110 of the mask frame 2100 and having the plurality of pixel openings 2212 and the grid region 2220 disposed on the rib region 2120 of the mask frame 2100. In particular, the cell regions 2210 of the membrane 2200 may have a residual tensile stress, and the grid region 2220 of the membrane 2200 may have a residual compressive stress.

According to this embodiment, the deposition mask 2000 may include the protective film 2400 disposed on the cell regions 2210. In some aspects, the intermediate regions 2230 may be disposed between the cell regions 2210 and the grid region 2220 of the membrane 2200. For example, the protective film 2400 may include a metal oxide or a metal nitride, and may be formed not only on the cell regions 2210 but also on the grid region 2220 and intermediate regions 2230 through an ALD process. In this embodiment, the protective film 2400 is substantially the same as that described herein with reference to FIG. 14, and the intermediate regions 2230 are substantially the same as those described herein with reference to FIGS. 15 and 16. In some aspects, since the remaining components except for the protective film 2400 and the intermediate regions 2230 are substantially the same as those described herein with reference to FIGS. 11 to 13, detailed descriptions thereof will be omitted.

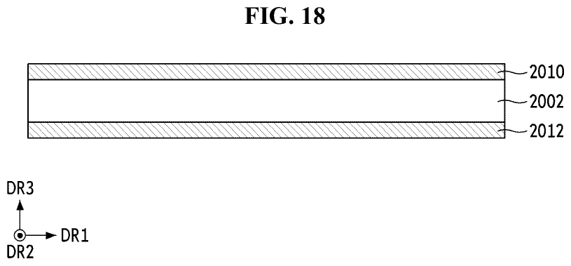

FIGS. 18 to 24 are schematic cross-sectional views illustrating a method of manufacturing a deposition mask according to still another embodiment of the present disclosure.

Referring to FIGS. 18 to 22, the method may include forming the membrane 2200 including the cell regions 2210 and the grid region 2220 on a substrate (or a mask substrate) 2002. Specifically, as illustrated in FIG. 18, the method may include forming, on the substrate 2002, a first inorganic film 2010 having residual tensile stress. The first inorganic film 2010 may include silicon nitride and may be formed through a TCVD process. For example, a silicon wafer may be used as the substrate 2002, and the first inorganic film 2010 may be formed such that the first inorganic film 2010 has a thickness of about 0.5 μm to about 3 μm by a batch type deposition apparatus (not illustrated). In this case, the first inorganic film 2010 may be formed on a front surface of the substrate 2002, and a rear inorganic film 2012 may be formed on a rear surface of the substrate 2002. That is, both the first inorganic film 2010 and the rear inorganic film 2012 may be formed of silicon nitride, and the rear inorganic film 2012 may have a residual tensile stress equal to the residual tensile stress of the first inorganic film 2010.

For example, the method may include supplying dichlorosilane (DCS, SiH₂Cl₂) gas used as a source gas and ammonia (NH₃) gas used as a reaction gas into a process chamber of the batch type deposition apparatus, for deposition of the first inorganic film 2010 and the rear inorganic film 2012. By appropriately adjusting the supply flow rates of the source gas and the reaction gas, the pressure and temperature inside the process chamber, and the like, the first inorganic film 2010 and the rear inorganic film 2012, which have a residual tensile stress of about 300 MPa to about 500 MPa, may be formed on the front and rear surfaces of the substrate 2002, respectively. However, the types of the source gas and reaction gas may be changed and thus, the scope of the present disclosure will not be limited thereby.

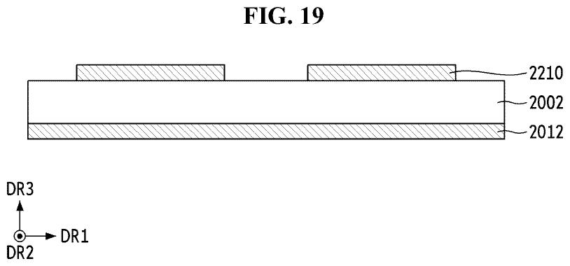

Referring to FIG. 19, the method may include forming the cell regions 2210 by patterning the first inorganic film 2010. For example, after forming a photoresist pattern (not illustrated), which exposes the remaining portion except for the portions where the cell regions 2210 are to be formed, on the first inorganic film 2010, the method may include forming the cell regions 2210 on the substrate 2002 by performing an anisotropic etching process using the photoresist pattern as an etch mask. After forming the cell regions 2210, the method may include removing the photoresist pattern through a stripping and/or ashing process.

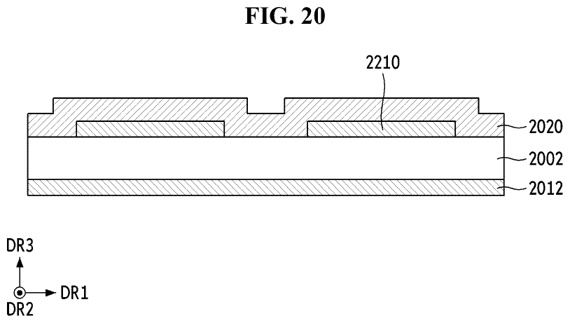

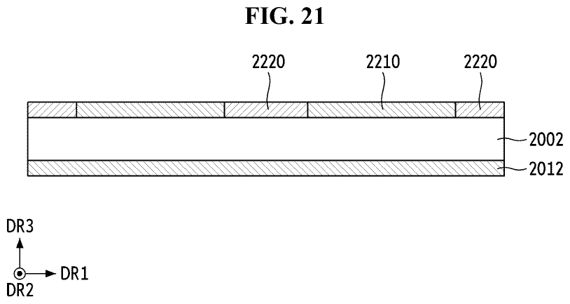

Referring to FIGS. 20 and 21, the method may include forming the grid region 2220 between the cell regions 2210. Specifically, as illustrated in FIG. 20, the method may include forming a second inorganic film 2020 having residual compressive stress on the substrate 2002 and the cell regions 2210. As illustrated in FIG. 21, the method may include partially removing the second inorganic film 2020 by performing a planarization process, in which partially removing the second inorganic film 2020 exposes the cell regions 2210, thereby forming the grid region 2220 between the cell regions 2210.

For example, the second inorganic film 2020 may include silicon nitride, and the method may include forming the second inorganic film 2020 by a PECVD process such that the second inorganic film 2020 has a thickness equal to or greater than the respective thicknesses of the cell regions 2210. In this case, DCS gas may be used as the source gas, and ammonia gas may be used as the reaction gas. In particular, while performing the PECVD process, the method may include appropriately adjusting the supply flow rates of the source gas and the reaction gas, the radio frequency (RF) power for plasma formation, the height of the chuck on which the substrate 2002 is mounted, the temperature of the substrate 2002, and the pressure inside the processing chamber, and the like, thereby adjusting the residual stress of the second inorganic film 2020. For example, the method may include forming the second inorganic film 2020 such that the second inorganic film 2020 has a residual compressive stress of about-500 MPa to about-300 MPa through the PECVD process.

After forming the second inorganic film 2020, the method may include performing a planarization process such as, for example, a chemical mechanical polishing (CMP) process. In this case, the method may include performing the CMP process until the cell regions 2210 are exposed, thereby forming the grid region 2220 between the cell regions 2210.

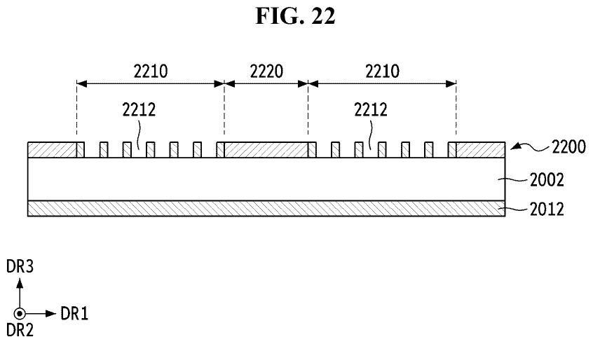

Referring to FIG. 22, the method may include forming the plurality of pixel openings 2212 which penetrate each of the cell regions 2210. Thus, the membrane 2200, which includes the cell regions 2210 having the pixel openings 2212 and the grid region 2220 disposed between the cell regions 2210, may be formed on the substrate 2002. For example, the method may include forming a photoresist pattern (not illustrated) on the cell regions 2210 and the grid region 2220 to expose the portions where the pixel openings 2212 are to be formed, and the method may include forming the pixel openings 2212 by performing an anisotropic etching process using the photoresist pattern as an etch mask. In this case, the method may include performing the anisotropic etching process until the surface of the substrate 2002 is exposed. The method may include removing the photoresist pattern through a stripping and/or ashing process after forming the pixel openings 2212.

As another example, although not illustrated, the method may include forming a buffer oxide film (not illustrated) on the substrate 2002. In this case, the buffer oxide film may be used as an etch stop film in the etching process for forming the cell regions 2210 and the etching process for forming the pixel openings 2212. For example, the method may include forming silicon oxide films (not illustrated) on the front and rear surfaces of the substrate 2002 through a thermal oxidation process. In this case, the first inorganic film 2010 and the rear inorganic film 2012 may be formed on the silicon oxide films.

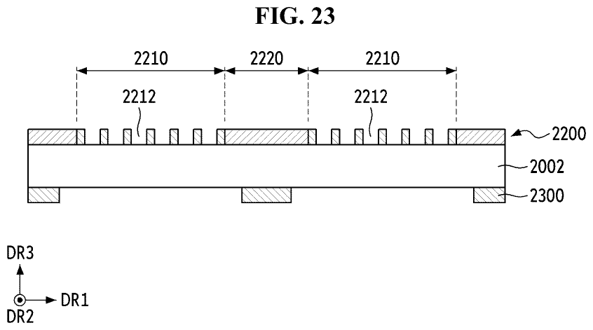

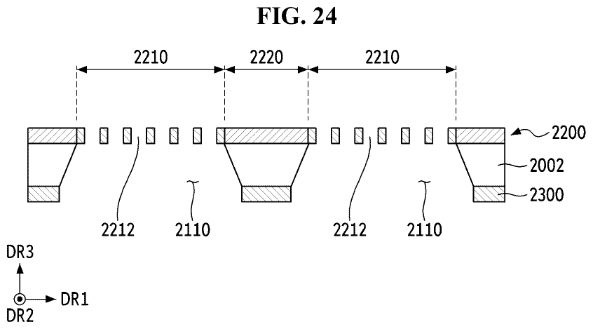

Referring to FIGS. 23 and 24, the method may include forming the cell openings 2110, which respectively expose the cell regions 2210, by partially removing the substrate 2002. Specifically, as illustrated in FIG. 23, the method may include forming, by patterning the rear inorganic film 2012, the inorganic film pattern 2300 that exposes the portions where the cell openings 2110 are to be formed. For example, after forming a photoresist pattern (not illustrated) on the rear inorganic film 2012 to partially expose the rear inorganic film 2012, the method may include forming the inorganic film pattern 2300 by performing an anisotropic etching process using the photoresist pattern as an etch mask. The method may include removing the photoresist pattern through a stripping and/or ashing process after forming the inorganic film pattern 2300.

Subsequently, as illustrated in FIG. 24, the method may include performing an anisotropic etching process using the inorganic film pattern 2300 as an etch mask, thereby forming the cell openings 2110 that penetrate the substrate 2002 and expose the cell regions 2210, respectively. For example, the method may include partially removing the substrate 2002 through a wet etching process using an aqueous solution of tetramethylammonium hydroxide (TMAH) or an aqueous solution of potassium hydroxide (KOH). The method may include performing the wet etching process until bottom surfaces of the cell regions 2210 are exposed, thereby forming the cell openings 2110 that communicate with the pixel openings 2212 of the cell regions 2210.

According to still another embodiment of the present disclosure, after forming the cell openings 2110 as described herein, the method may include additionally forming the protective film 2400 on the cell regions 2210, the grid region 2220, and the mask frame 2100 through the ALD process as illustrated in FIG. 14.

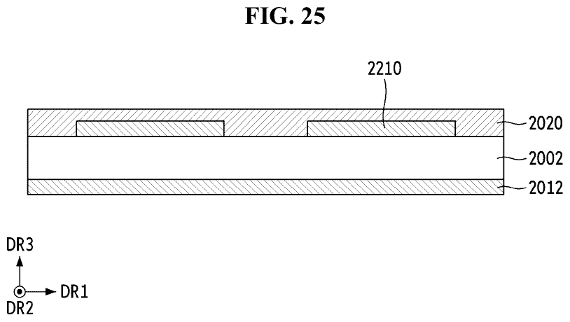

FIGS. 25 to 31 are schematic cross-sectional views illustrating a method of manufacturing a deposition mask according to still another embodiment of the present disclosure.

Referring to FIG. 25, the method may include forming the first inorganic film 2010 and the rear inorganic film 2012 on the front and rear surfaces of the substrate 2002, respectively. Subsequently, the method may include forming the cell regions 2210 by patterning the first inorganic film 2010, and forming the second inorganic film 2020 on the substrate 2002 and the cell regions 2210. In this case, the method may include forming the first inorganic film 2010 and the rear inorganic film 2012 such that the first inorganic film 2010 and the rear inorganic film 2012 each have a residual tensile stress, and the method may include forming the second inorganic film 2020 such that the second inorganic film 2020 has a residual compressive stress. In this embodiment, the method of forming the first inorganic film 2010, the rear inorganic film 2012, the cell regions 2210, and the second inorganic film 2020 may be substantially the same as that described herein with reference to FIGS. 18 to 20, and a detailed description thereof will be omitted.

After forming the second inorganic film 2020, the method may include performing a planarization process such as, for example, a CMP process which planarizes the second inorganic film 2020 as illustrated in FIG. 25. In this case, the second inorganic film 2020 may be formed such that the thickness of the second inorganic film 2020 is greater than the respective thicknesses of the cell regions 2210, that is, the first inorganic film 2010, and accordingly, the second inorganic film 2020, which has been planarized through the CMP process, may be formed on the substrate 2002 and the cell regions 2210. As another example, the method may include performing the CMP process until the cell regions 2210 are exposed. In this case, the grid region 2220 may be formed between the cell regions 2210.

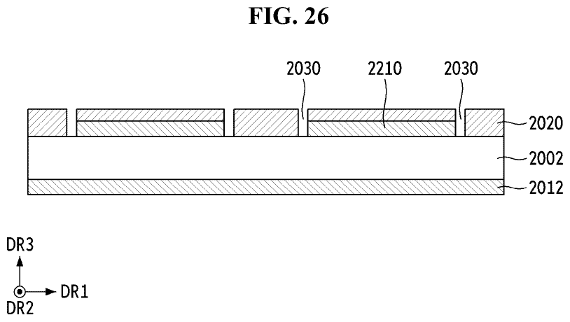

Referring to FIG. 26, the method may include forming, by patterning the second inorganic film 2020, trenches 2030 that respectively surround the cell regions 2210. For example, the method may include forming a photoresist pattern (not illustrated) on the second inorganic film 2020 which exposes the portions where the trenches 2030 are to be formed, and the method may include forming the trenches 2030 respectively surrounding the cell regions 2210 by performing an anisotropic etching process using the photoresist pattern as an etch mask. In this case, the method may include performing the anisotropic etching process until the substrate 2002 is exposed, and the method may include removing the photoresist pattern through a stripping and/or ashing process after forming the trenches 2030. As another example, while performing the anisotropic etching process, edge portions of the cell regions 2210 may be partially removed.

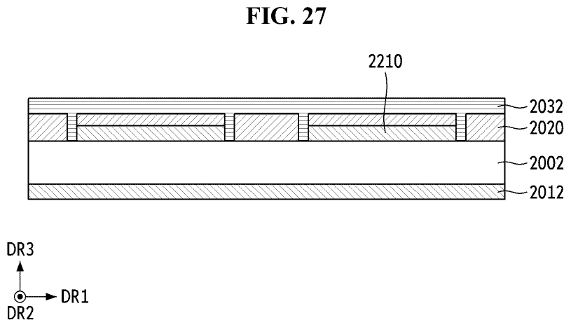

Referring to FIG. 27, the method may include forming, on the second inorganic film 2020, a third inorganic film 2032 which fills the trenches 2030. For example, the third inorganic film 2032 may include silicon nitride, and the method may include forming the third inorganic film 2032 to fill the trenches 2030 through a PECVD process. In this case, DCS gas may be used as the source gas, and ammonia gas may be used as the reaction gas. In particular, while performing the PECVD process, the method may include appropriately adjusting the supply flow rates of the source gas and the reaction gas, the RF power for plasma formation, the height of the chuck on which the substrate 2002 is mounted, the temperature of the substrate 2002, the pressure inside the process chamber, and the like, thereby adjusting the residual stress of the third inorganic film 2032. According to this embodiment, the third inorganic film 2032 may be formed through the PECVD process such that the third inorganic film 2032 has a residual stress ranging from about-500 MPa to about 500 MPa.

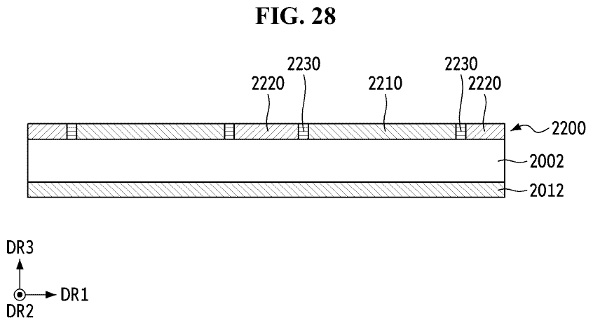

Referring to FIG. 28, after forming the third inorganic film 2032, the method may include performing a planarization process such as, for example, a CMP. In this case, the method may include performing the CMP process until the cell regions 2210 are exposed, thereby forming the grid region 2220 between the cell regions 2210, and also forming the intermediate regions 2230 between the cell regions 2210 and the grid region 2220. That is, the intermediate regions 2230 respectively surrounding the cell regions 2210 may be ring-shaped and respectively formed in the trenches 2030.

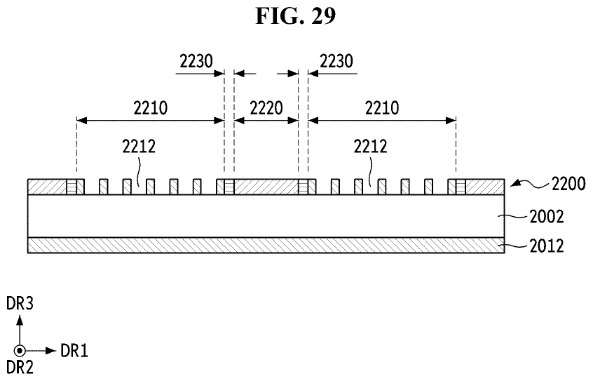

Referring to FIG. 29, the method may include forming the plurality of pixel openings 2212 which penetrate each of the cell regions 2210. Thus, the membrane 2200, which includes the cell regions 2210 having the pixel openings 2212, the grid region 2220 disposed between the cell regions 2210 and the intermediate regions 2230 disposed between the cell regions 2210 and the grid region 2220, may be formed on the substrate 2002. In this embodiment, the method of forming the pixel openings 2212 may be substantially the same as that described herein with reference to FIG. 22, and a description thereof will be omitted.

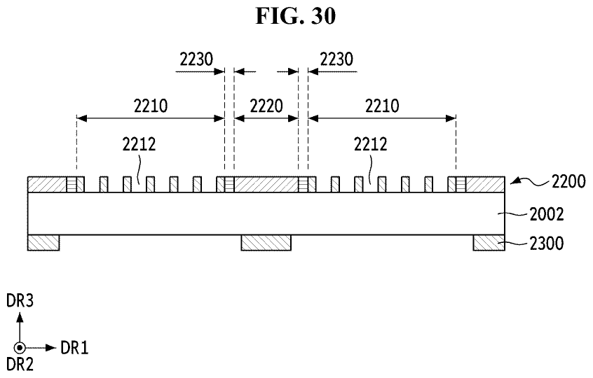

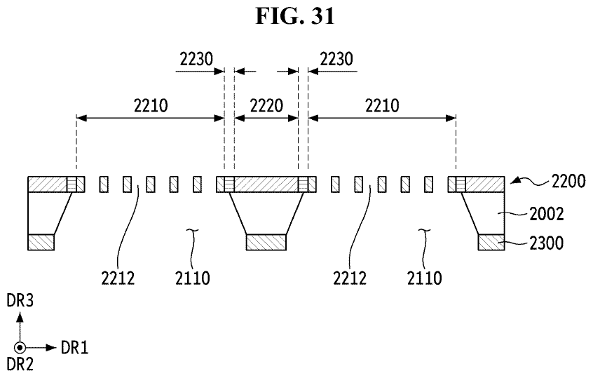

Referring to FIGS. 30 and 31, the method may include forming, by partially removing the substrate 2002, the cell openings 2110 that expose the cell regions 2210, respectively. Specifically, as illustrated in FIG. 30, the method may include forming, by patterning the rear inorganic film 2012, the inorganic film pattern 2300 that exposes the portions where the cell openings 2110 are to be formed. As illustrated in FIG. 31, the method may include forming, by performing an anisotropic etching process using the inorganic film pattern 2300 as an etch mask, the cell openings 2110 that penetrate the substrate 2002 and respectively expose the cell regions 2210. In this embodiment, the method of forming the inorganic film pattern 2300 and the cell openings 2110 may be substantially the same as that described herein with reference to FIGS. 23 and 24, and a detailed description thereof will be omitted.

According to still another embodiment of the present disclosure, after forming the cell openings 2110 as described herein, the method may include additionally forming the protective film 2400 on the cell regions 2210, the grid region 2220, the intermediate regions 2230, and the mask frame 2100 through the ALD process as illustrated in FIG. 17. In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Example aspects supported by the present disclosure should not be construed as being limited to the embodiments set forth herein. Rather, the example embodiments are provided such that this disclosure will be thorough and complete and will fully convey the concepts supported by the present disclosure to those skilled in the art.

While the example aspects supported by the present disclosure have been particularly illustrated and described with reference to embodiments thereof, it will be understood by those of ordinary skill in the art that various changes in form and details may be made therein without departing from the spirit or scope of the concepts supported by the present disclosure as defined by the following claims.

What is claimed is:

1. A deposition mask comprising:
a mask frame comprising:
a plurality of cell openings; and
a rib region defining the cell openings; and
a membrane comprising:
a plurality of cell regions respectively disposed above the cell openings and each having a plurality of pixel openings; and
a grid region disposed on the rib region,
wherein the cell regions have a residual tensile stress, and the grid region has a residual compressive stress.

2. The deposition mask of claim 1, wherein:
the residual tensile stress ranges from about 300 MPa to about 500 MPa, and
the cell regions are formed of an inorganic material.

3. The deposition mask of claim 1, wherein:
the residual compressive stress ranges from about-500 MPa to about-300 MPa, and
the grid region is formed of an inorganic material.

4. The deposition mask of claim 1, wherein the membrane further comprises intermediate regions disposed between the cell regions and the grid region and respectively surrounding the cell regions.

5. The deposition mask of claim 4, wherein the intermediate regions have a residual stress ranging from about-500 MPa to about 500 MPa and are formed of an inorganic material.

6. The deposition mask of claim 4, wherein each of the intermediate regions is partially exposed by a cell opening of the cell openings.

7. The deposition mask of claim 1, further comprising an inorganic film pattern disposed on a rear surface of the mask frame.

8. The deposition mask of claim 7, wherein the inorganic film pattern has a residual stress equal to the residual stress of the cell regions.

9. The deposition mask of claim 1, further comprising a protective film disposed on the cell regions.

10. The deposition mask of claim 9, wherein the protective film comprises a metal oxide or a metal nitride.

11. A method of manufacturing a deposition mask, comprising:
forming a membrane on a substrate, the membrane comprising cell regions and a grid region disposed between the cell regions; and
forming cell openings which respectively expose the cell regions by partially removing the substrate,
wherein the cell regions have a residual tensile stress, and the grid region has a residual compressive stress.

12. The method of claim 11, wherein the forming of the membrane comprises:
forming, on the substrate, a first inorganic film having the residual tensile stress;
forming the cell regions by patterning the first inorganic film; and
forming the grid region between the cell regions.

13. The method of claim 12, wherein the forming of the grid region comprises:
forming, on the substrate and the cell regions, a second inorganic film having the residual compressive stress; and
forming the grid region between the cell regions by performing a planarization process, wherein the grid region exposes the cell regions.

14. The method of claim 12, wherein the forming of the membrane further comprises:
forming intermediate regions respectively surrounding the cell regions, between the cell regions and the grid region.

15. The method of claim 14, wherein:
the residual tensile stress ranges from about 300 MPa to 500 MPa,
the residual compressive stress ranges from about-500 MPa to about-300 MPa, and
the intermediate regions have a residual stress ranging from about-500 MPa to about 500 MPa.

16. The method of claim 12, further comprising forming a rear inorganic film on a rear surface of the substrate,
wherein the forming of the cell openings comprises:
forming, by patterning the rear inorganic film, an inorganic film pattern exposing portions where the cell openings are to be formed; and
performing an etching process using the inorganic film pattern as an etch mask in association with forming the cell openings.

17. The method of claim 16, wherein the first inorganic film and the rear inorganic film are formed simultaneously through a thermal chemical vapor deposition process.

18. The method of claim 11, wherein the forming of the membrane comprises:
forming, on the substrate, a first inorganic film having the residual tensile stress;
forming the cell regions by patterning the first inorganic film;
forming, on the substrate and the cell regions, a second inorganic film having the residual compressive stress;
performing an etching process which forms trenches respectively surrounding the cell regions;
forming a third inorganic film which fills the trenches; and
performing a planarization process which exposes the cell regions,
wherein the grid region is formed between the cell regions by the planarization process, and intermediate regions respectively surrounding the cell regions are formed between the cell regions and the grid region by the planarization process.

19. The method of claim 11, further comprising:
forming, at each cell region of the cell regions, a plurality of pixel openings penetrating the cell region; and
after forming the cell openings, forming a protective film on the cell regions.

20. An electronic device comprising a display panel,
wherein the display panel comprises a backplane substrate and light-emitting layers formed on the backplane substrate by using a deposition mask,
wherein the deposition mask comprises:
a mask frame comprising:
a plurality of cell openings; and
a rib region defining the cell openings; and
a membrane comprising:
a plurality of cell regions respectively disposed above the cell openings and each having a plurality of pixel openings; and
a grid region disposed on the rib region,
wherein the cell regions have a residual tensile stress, and the grid region has a residual compressive stress.
